(19) United States
(12) Patent Application Publication
(10) Pub. No.: US 2020/0348588 A1
(43) Pub. Date: Nov. 5, 2020

(54) Framework for a replication device, replication device as well as method for producing nanostructured and/or microstructured components by means of a replication device

(71) Applicant: SUSS MicroTec Lithography GmbH, Garching (DE)

(72) Inventors: Raoul KIRNER, Garching (DE); Wilfried NOELL, Garching (DE); Andreas NAGY, Garching (DE)

(21) Appl. No.: 16/866,254

(22) Filed: May 4, 2020

(30) Foreign Application Priority Data
May 2, 2019 (NL) 2023051

(51) Int. Cl. G03F 7/00; G03F 7/20

(52) U.S. Cl. CPC G03F 7/0002; G03F 7/70775

(57) ABSTRACT

A framework for a replication device for producing nanostructured and/or microstructured components forms a gimbal suspension. In addition, a replication device is provided including such a framework. Further, a method is described for producing nanostructured and/or microstructured components by imprint lithography using a replication device.

### FIELD OF THE DISCLOSURE

The disclosure relates to a framework for a replication device for producing nanostructured and/or microstructured components as well as a replication device comprising such a framework. The disclosure also relates to a method for producing nanostructured and/or microstructured components by means of imprint lithography by means of a replication device.

### BACKGROUND

Methods for producing nanostructured and/or microstructured components by means of imprint lithography are well-known. In this case, a stamp comprising a nanostructured and/or microstructured stamp surface is pressed into a replication material on a substrate in order to form a corresponding complementary nanostructure and/or microstructure in the replication material.

In this case, a typical replication device that is used comprises a holding means in each case for holding the stamp as well as the substrate. These holding means are usually adjustably mounted or suspended in order to ensure a parallel alignment of the stamp surface and the surface of the substrate and the replication material.

Known replication devices have the disadvantage that the holding means are designed very complexly in order make it possible to ensure an adjustable, but simultaneously precise alignment of the stamp or the substrate.

Another challenge in imprint lithography is removing the stamp from the replication device without damaging to the nanostructure and/or microstructure that is formed in the replication material as a result of the adhesion of the stamp and the replication material.

### SUMMARY

Thus, there is a need to provide a framework for a replication device, a replication device as well as a method for producing nanostructured and/or microstructured components by means of imprint lithography by means of a replication device that ensures the detachment of the stamp from the replication material using particularly low forces in order to achieve a high quality of the nanostructure and/or microstructure generated in the replication material.

A framework for a replication device for producing nanostructured and/or microstructured components by means of a lithographic method is provided in order to solve the object. The framework has a fixture as well as first frame and a second frame. The first frame is connected to the fixture by means of a first joint, wherein the first joint defines a first rotational axis about which the first frame is pivotable relative to the fixture. The second frame is connected to the first frame by means of a second joint, wherein the second joint defines a second rotational axis about which the second frame is pivotable relative to the first frame. Furthermore, the second frame comprises a holder for a head, such as a stamp, a mask and/or a substrate, and thus forms the holding means for the corresponding head.

The first frame is in particular only pivotable relative to the fixture about the first rotational axis and the second frame is only pivotable relative to the first frame about the second rotational axis.

In this case, the fixture, the first frame and second frame collectively form a gimbal suspension or mounting. These passive mechanics are characterized by a simple assembly and ensure a precise alignment of the head at the same time.

In the case of a replication device that is provided to produce nanostructured and/or microstructured components by means of imprint lithography, a wedge error between the stamp and the substrate can be compensated passively by means of the framework, thus providing a defined alignment of the stamp surface to the surface of the substrate or the replication material applied to the substrate.

The framework, in particular the holder of the framework, serves for example as a stamp holding means for an imprint stamp. In this case, the replication device comprises a fixture for a substrate or a further stamp below the framework. An imprinting of structures can occur by moving the imprint stamp and the substrate or a further stamp against each other.

The movement of the imprint stamp and thus the framework towards the substrate occurs in a downfeed direction that is defined by the replication device and in particular its downfeed mechanics.

Furthermore, the replication device comprises a reference plane that extends perpendicular to the downfeed direction and comprises a defined fixed position relative to the replication device.

The reference plane can coincide with a replication area of the replication device at least in sections or run parallel to it.

The replication area of the replication device is the area in which the nanostructure and/or microstructure of the components are formed when the replication device for producing nanostructured and/or microstructured components is operated.

In the case of a replication device that is provided to produce nanostructured and/or microstructured components by means of another lithographic method, such as photo lithography, in which no downfeed movement occurs between the framework and a substrate or a stamp, the reference plane can be formed parallel to a chuck of the replication device and/or at least in sections by the surface of the substrate or the stamp opposite to the framework.

The nanostructured and/or microstructured components are in particular semiconductor or micro-optical components.

In this case, the framework is provided for a replication device for producing nanostructured and/or microstructured components by means of a lithographic method, in particular a nano-imprint lithographic method, a step-and-repeat method, a microlithographic method and/or a photo lithographic method.

The fixture comprises an attaching element, by means of which the fixture is attachable to the replication device.

Preferably, the first rotational axis and the second rotational axis run perpendicular to each other, thereby enabling the framework to be assembled more easily, for example symmetrically.

It is advantageous if the first rotational axis and second rotational axis run in a plane as the stamp can thereby comprise a symmetrical displacement behavior and the framework can be designed particularly compactly. In the case of a framework for an imprint lithographic method, the stamp can thus be attached to the holder in such a way that the spacing is particularly small between the structure-forming stamp surface and both rotational axes. This is advantageous as the lateral offset of the stamp surface relative to the substrate or the replication material is particularly small in the case of a displacement of the stamp about the first and/or second rotational axis.

In addition or alternatively, the first rotational axis and the second rotational axis can run parallel to a reference plane of the replication device and/or the holder, thereby enabling the framework to be designed more compactly.

In an embodiment, the holder is aligned in a neutral position of the framework obliquely to a reference plane, in particular at an angle between 0° and 5°, preferably from 1° to 2°. The alignment of the holder is thus defined by a plane that runs parallel to the structure defining surface of the head placed in the holder. In the case of a stamp for imprint lithography, this is the structure-forming stamp surface.

By thus deviating the alignment of the holder to the reference plane by this angle from the parallel position, it is possible in the case of the imprint lithographic method to provide an asymmetrical force in the stamp in the form of a gradient that runs in the direction of the inclination so that forces of differing magnitudes act on different ends of the stamp between the stamp surface and the replication material when removing the stamp from the replication material. Thus, the stamp surface is removed asymmetrically from the surface of the replication material, thereby enabling the separation of the stamp from the replication material in a way that prevents damage. As a result, the quality of the formed nanostructure and/or microstructure can be increased.

The inclined position of the holder, i.e. the alignment of the holder at an angle relative to the reference plane, is provided in particular by means of an intrinsic prestressing of the first and/or the second joint.

In another embodiment, the first joint and the second joint comprise only one degree of freedom each, namely the rotation about the first or second rotational axis, while all other degrees of freedom are locked. In particular, the framework is also configured to be free from play. This is advantageous as the head can be supported and aligned by the framework in a well-defined way, thereby ensuring a high quality of the nanostructured and/or microstructured component formed by means of the head.

According to an embodiment, the first and/or second joint are each a solid-state joint, in particular a cross-spring joint. Solid-state joints are free from play, thereby enabling the head to be mounted or aligned more precisely by means of the framework.

In this regard, solid-state joints can be provided as return springs that apply a force to the framework and/or the holder or its alignment in the direction of a neutral position in order to thus provide a defined starting position.

In accordance with a further embodiment, the framework comprises at least a first elastic element, by means of which the fixture is elastically connected to the first frame, in particular under prestress. In addition or alternatively, the framework comprises at least a second elastic element, by means of which the first frame is elastically connected to the second frame, in particular under prestress. In this way, the frames are connected elastically.

In the case of a framework for a replication device that operates using an imprint lithographic method, a defined restoring force can be provided by means of the elastic elements, said restoring force acting on the holder and thus on a stamp attached in the holder if the stamp with the holder is displaced from the neutral position during an imprint process. This is the case, for example, if the stamp is pressed into a replication material and the neutral position does not run parallel to the surface of the replication material.

Furthermore, by means of elastic elements, different torques can be compensated in the framework that are introduced into the system as a result of the configuration of the gimbal suspension, for example due to the weight of the frames, the alignment of the rotational axes and/or the configuration of the joints.

In addition, a torque can be applied to a stamp attached in a holder by means of the elastic elements so that the restoring force is distributed asymmetrically over the stamp surface, i.e. the restoring force is different in magnitude at different points of the stamp surface. In particular, the restoring force can change from one end of the stamp surface to the opposite end of the stamp surface in the form of a gradient. This configuration aids the detachment of the stamp from the replication material, thereby enabling an improvement to the quality of the nanostructures and/or microstructures formed by the stamp.

At least some of the elastic elements can be adjustable mechanically and/or electrically, in particularly piezoelectrically. By this means, the alignment and/or the restoring force of the holder can be adjusted if the holder is displaced from its neutral position. Moreover, the framework can be adjusted by means of the adjustable elastic elements, in particular in order to compensate intrinsic torques.

In an embodiment, the first elastic element and/or the second elastic element are each a spring, in particular an adjustable spring, i.e. a spring by means of which the spring force and/or spring travel can be adjusted. Springs are economical and reliably provide a defined restoring force.

In this case, at least two first elastic elements and/or at least two second elastic elements can be provided. The first two elastic elements thus apply different restoring forces and/or the two second elastic elements apply different restoring forces.

For example, the two first elastic elements are located on different sides of the first rotational axis. The two first elastic elements apply a force to the first frame in the direction of a position that is rotated in relation to a position that the first frame occupies if two first elastic elements have applied forces to the first frame that are of the same magnitude but are opposing. In other words, the asymmetrical application of force on the frame results in an inclined position in relation to a zero position. The same applies accordingly to the two second elastic elements and the second rotational axis as well as the position of the second frame.

The framework can comprise a first stop that limits the rotation of the first frame to the fixture about the first rotational axis. In addition or alternatively, the framework can comprise a second stop that limits the rotation of the second frame to the first frame about the second rotational axis. In this way, the maximum displacement of the first and second frame can be limited effectively. As a result of this limitation, damage to the framework, in particular the elastic elements, can be prevented reliably.

In this regard, the stops can be designed adjustably, in particular individually, in order to offer further adjustment capabilities for adapting the framework to different requirements.

In an embodiment, at least some of the stops and at least some of the elastic elements are each configured as a combined assembly, i.e. one stop and one element form a common assembly. This is advantageous as the assemblies and thus the framework can be configured particularly compactly.

For example, the minimum spacing between the holder and the first rotational axis and/or the second rotational axis is a maximum of 15 mm, preferably a maximum of 10 mm.

In addition or alternatively, the minimum spacing between the reference plane and the first rotational axis and/or the second rotational axis is a maximum of 15 mm, preferably a maximum of 10 mm.

In the case of a framework for a replication device that is provided for producing nanostructured and/or microstructured components by means of imprint lithography, the minimum spacing between the stamp surface of the stamp attached in the holder and the first rotational axis and/or the second rotational axis is a maximum of 15 mm, preferably a maximum of 10 mm.

A small spacing is advantageous in the aforementioned cases as the lateral offset of the stamp surface relative to the substrate or the replication material is particularly small in the case of a displacement of the stamp about the first and/or second rotational axis.

In a further embodiment, the first frame and the second frame are arranged with one within the other, preferably concentrically. This means, the first frame is located within the second frame, wherein the second frame surrounds the first frame at least in sections, or the second frame is located within the first frame, wherein the first frame surrounds the second frame at least in sections. As a result, the framework is particularly compact.

According to an embodiment, the framework comprises a channel that extends perpendicularly away from the holder through the fixture, the first frame and/or the second frame. In this way, the channel can form a ray path for a light source. Thus, the mask or the stamp in the holder can be illuminated directly or indirectly by means of the light source.

According to the disclosure, a replication device comprising a framework according to the disclosure with the aforementioned advantages is also provided to solve the aforementioned object.

The replication device comprises a mount for the framework, on which the framework is attachable by means of at least one corresponding attaching element.

In an embodiment, the framework is moveable perpendicular to a reference plane of the replication device so that the spacing of the holder to the reference plane can be changed, in particular automatically.

In a further embodiment, the replication device comprises a light source and a ray path that extends from the holder to the light source. In this way, the mask or the stamp in the holder can be illuminated, in particular directly, in the direction of the replication area by means of the light source.

In order to solve the aforementioned object according to the disclosure, a method for producing nanostructured and/or microstructured components by means of a lithographic method, in particular a nano-imprint lithographic method, by means of a replication device, in particular a replication device according to the disclosure is also provided comprising the following steps:
a) providing a substrate;
b) providing a stamp in a holder of the replication device,
c) moving the stamp and/or the holder and the substrate towards each other relatively so that the stamp and the substrate occupy a parallel position to each other and a replication material provided between the stamp and the substrate is imprinted by the stamp, and
d) detaching the stamp, wherein the stamp is prestressed and/or moved in a direction from the parallel position by a force.

In particular between steps c) and d), i.e. after imprinting and before detaching the stamp, the replication material between the stamp and the substrate is cured in a further step and thus converted from a liquid phase to a solid phase, thereby fixing and thus maintaining the imprinted structure in the replication material.

This method is advantageous as forces of differing magnitudes act between the replication material and different points of the structure-forming stamp surface when detaching the stamp from the replication material, thereby favoring the detachment of the stamp from the replication material. As a result, the risk of damaging the nanostructures and/or microstructures formed by the stamp when detaching the stamp is reduced. Thus, nanostructures and/or microstructures of a high quality can be generated reliably by means of the method.

By prestressing and/or moving the stamp in a direction from the parallel position as a result of a force, a distribution of forces forms between the replication material and the structure-forming stamp surface, in the case of said variation of forces, the forces gradually decrease from one end of the stamp surface to the opposite end of the stamp surface. It is therefore possible to ensure that the replication material detaches continuously from one end of the stamp surface to the opposite end of the stamp surface. In other words, the stamp is removed from the replication material starting at one end of the stamp surface, in particular continuously.

The surface of the substrate which is facing the stamp can be a substantially even surface which is in particular in a reference plane of the replication device. Alternatively, the surface of the substrate can be a structured surface, an inclined surface and/or a curved, in particular concave, surface.

For example, an existing microstructure on a substrate surface is superimposed or modified with a nanostructure in the replication method.

In an embodiment, the stamp and/or the holder are aligned obliquely to the substrate, in particular at an angle between 0° and 5°, preferably from 1° to 2°, before the stamp and/or the holder and the substrate are moved relatively towards each other, wherein the stamp and/or the holder are prestressed in relation to the substrate by assuming the parallel position. In this regard, the holder is in the neutral position before the stamp contacts the replication material. If the stamp is pressed into the replication material during the imprint process, the stamp surface is aligned parallel to the substrate surface and the stamp is prestressed relative to the neutral position. In this way, the prestressing of the stamp is automatically provided during the imprint process by the elastically supported holder whose alignment deviates from the parallel position relative to the reference plane and the corresponding section of the replication area, thereby making the method particularly simple and efficient.

### DESCRIPTION OF THE DRAWINGS

Additional advantages and features can be found in the following description as well as the attached drawings. In these:

FIG. 1 shows a replication device comprising a framework according to the disclosure in a schematic representation.

FIG. 2 shows the framework from FIG. 1 in a zero position in a perspective representation,

FIG. 3 shows the framework from FIG. 1 in a zero position in a schematic representation, and

FIGS. 4 to 6 show a method according to the disclosure for producing nanostructured and/or microstructured components by means of a replication device from FIG. 1 in a schematic representation.

### DETAILED DESCRIPTION

Lists having a plurality of alternatives connected by “and/or”, for example “A, B and/or C” are to be understood to disclose an arbitrary combination of the alternatives, i.e. the lists are to be read as “A and/or B and/or C”. The same holds true for listings with more than two items.

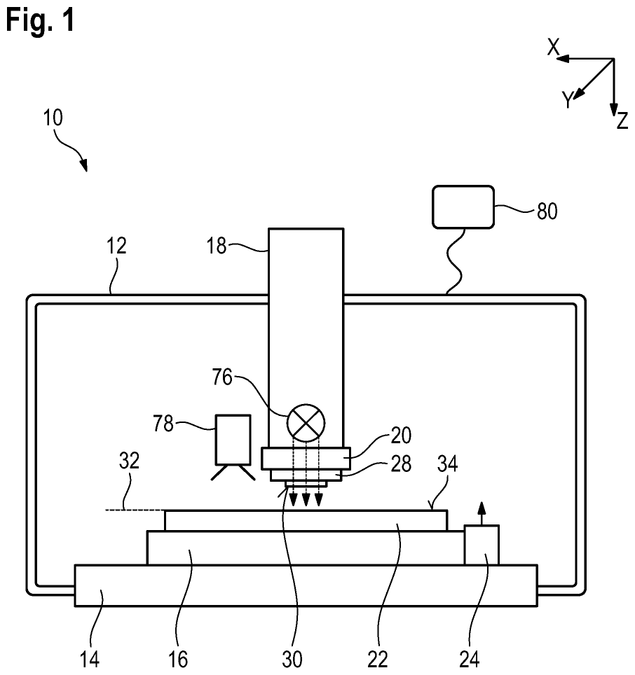

A replication device 10 for producing nanostructured and/or microstructured components is shown in FIG. 1. The replication device 10 has a machine frame 12, a XY table 14 comprising a chuck 16 as well as a support 18 comprising a framework 20.

The chuck 16 is positionable in the XY plane by means of the XY table 14. The Y axis extends perpendicular to the image plane in FIG. 1.

The chuck 16 is provided as a holding means for the substrate 22 that forms the main body of the nanostructured and/or microstructured component to be produced.

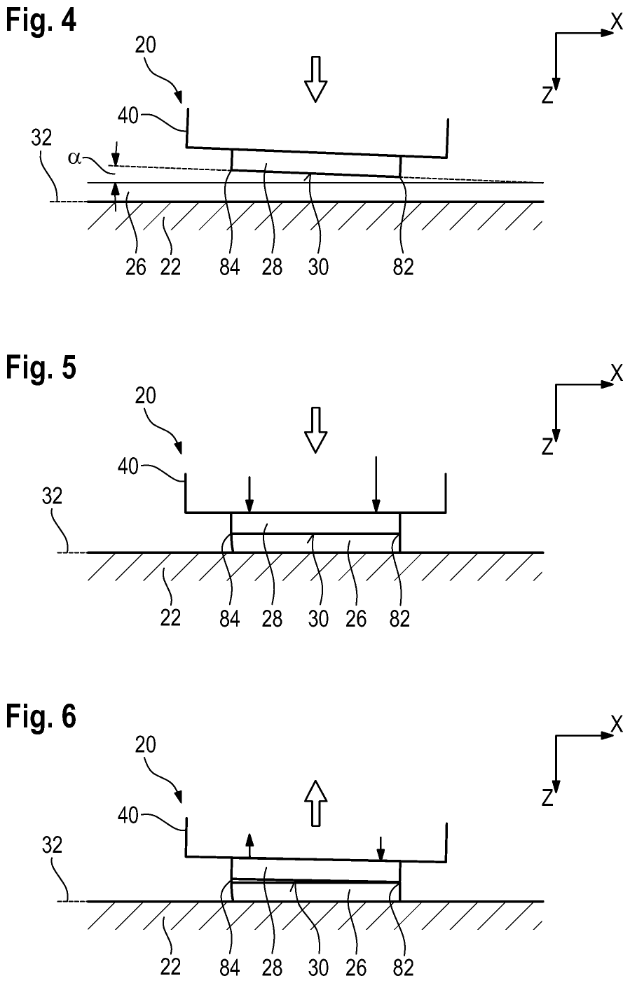

The replication device 10 comprises furthermore a metering unit 24, by means of which a liquid replication material 26 (see FIG. 4) can be applied to a stamp 28 in the form of a thin film or a drop.

The support 18 is attached to the machine frame 12 opposite the chuck 16 and is moveable by means of an actuator along the Z axis.

The framework 20 is attached to the support 18 opposite the chuck 16 and forms a holding means for a stamp 28 comprising a structure-forming stamp surface 30 that is provided for forming the nanostructure and/or microstructure in the substrate 22 or replication material 26.

The stamp surface 30 is macroscopically substantially planar, even if it comprises structures in the nano-range and/or micro-range on a microscopic level, in order to make it possible to form the nanostructure and/or microstructure to be replicated in the substrate 22 or the replication material 26.

The replication device 10 comprises a replication plane 32 that extends parallel to a XY plane and corresponds to the surface 34 of the substrate 22 in the present embodiment that is opposite the stamp surface 30 and forms here the replication area.

The surface 34 of substrate 22 is planar.

In an alternative embodiment, the replication surface can be formed in any way, in particular curved and/or structured.

In the shown embodiment, the replication device 10 is provided for the production of nanostructured and/or microstructured components by means of a step-and-repeat nanoimprint lithographic method.

The replication device 10 (see FIG. 1) comprises a light source 76 that is configured for curing the replication material 26.

The light source 76 is a UV lamp and the replication material 26 is a polymer that can be activated and cured by means of UV radiation.

The light source 76 is provided in the support 18 on the side of the holding means for the stamp 28 facing away from the reference plane 32.

The stamp 28 is at least partially transparent for UV light so that the UV light of the light source 76 falls on the replication material 26 through the stamp 28 and can cure the replication material 26.

Of course, the framework 20 and/or the stamp holding means can be at least transparent in sections for UV light, in particular the sections of the framework 20 that are located in the ray path between the light source 76 and the stamp 28.

Furthermore, the replication device 10 has a camera 78 that is part of an imaging processing system that is provided for the process monitoring of the replication process.

In an alternative embodiment, the replication device 10 can be configured to produce nanostructured and/or microstructured components by means of any imprint lithographic method or another method, for example a microlithographic method and/or a photo lithographic method.

In particular, the framework 20 can be provided in an alternative embodiment, in addition or alternatively to a holding means for a stamp 28, as a holding means for a mask, for example a photomask, a lens array and/or a substrate. In these cases, the holder 48 can be configured accordingly to ensure a secure attachment of the corresponding head, i.e. stamp, mask, substrate or lens array.

The replication device 10 is connected to a control unit 80 in which information for the nanostructured and/or microstructured component to be produced is stored and which controls the production processes.

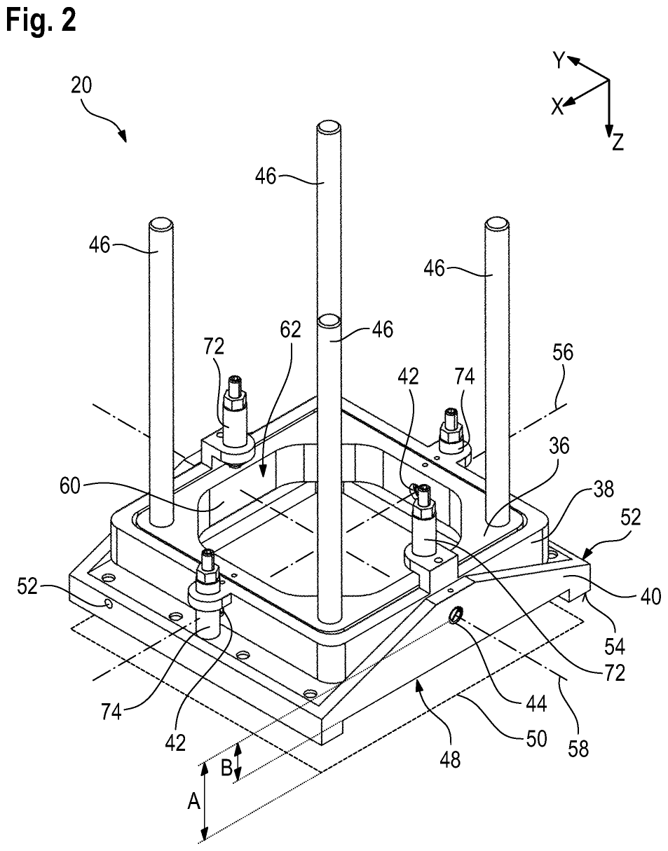

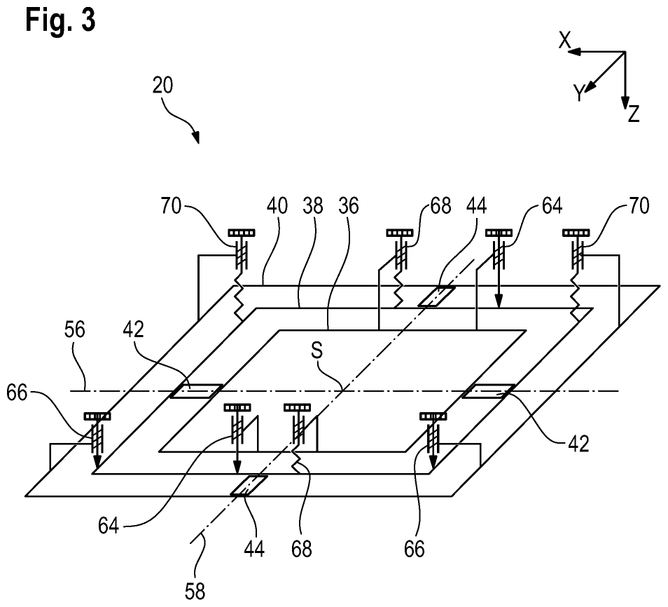

The framework 20 (see FIGS. 2 and 3) comprises a fixture 36, a first frame 38 and a second frame 40 which are connected together via two first joints 42 and two second joints 44 and form a gimbal suspension, as explained below.

The fixture 36 has four attachment elements 46 extending in the Z axis, by means of which the fixture 36 is attached to the support 18. The attachment elements 46 are for example fixing rods.

To this end, the support 18 comprises a correspondingly designed mount for the framework in which the attachment elements 46 are inserted and in which they can be attached.

Of course, in an alternative embodiment, the framework 20 can be attached to the support 18 by means of the fixture 36 in any manner.

The second frame 40 has a holder 48 for the stamp 28 that is located on the framework 20 opposing the attachment elements 46 and faces the replication area in the assembled state. The holder 48 ensures a secure attachment of the stamp 28 to the framework 20 and is designed in such a way that that stamp surface 30 rests in a plane 50 that is spaced apart from the framework 20 in the Z direction. This ensures that the structure-forming stamp surface 30 can be imprinted into the replication material 26 in the imprint process in a defined way without the framework 20 coming into contact with the replication material 26.

In the present embodiment, the holder 48 is a vacuum pickup in which the stamp 28 is attached by means of a vacuum. To this end, the holder 48 comprises two vacuum connections 52 which are provided on opposing sides of the second frame 40 and via which the vacuum pickup is controllable.

In an alternative embodiment, the holder 48 can be formed in any way and/or can be an arbitrary holder for attaching the stamp 28. For example, the stamp 28 can be attached on the second frame 40 electrostatically and/or mechanically in an alternative embodiment.

The stamp surface 30 is quadratic and has, for example, a size of 10 mm×10 mm.

In an alternative embodiment, the stamp surface 30 can be formed in any way and can comprise any size. Preferably, the stamp surface 30 has a rectangular, in particular quadratic, shape comprising side lengths in a range from 5 mm to 20 mm.

The plane 50 is located parallel to the bottom side 54 of the second frame 40 which is opposite the replication area in an assembled state of the framework 20 and extends in the XY direction in FIG. 2.

The gimbal suspension of the framework 20 is configured as shown in FIG. 3 and described as follows.

The first frame 38 is coupled with the fixture 36 pivotably via the two first joints 42 and a first rotational axis 56 and the second frame 40 is coupled with the first frame 38 pivotably via the two second joints 44 about a second rotational axis 58.

The first rotational axis 56 and the second rotational axis 58 are perpendicular to one another and lie in a mutual plane so that they intersect at an angle of 90° at the intersection S.

In an alternative embodiment, the first frame 38 can be coupled with the fixture 36 pivotably via only one single first joint 42 and the first rotational axis 56 and/or the second frame 40 is coupled with the first frame 38 pivotably via only one single second joint 44 about the second rotational axis 58.

The advantage of the shown embodiment comprising two first joints 42 and two second joints 44 which are each located on opposing sides of the first frame 38 is that as a result the gimbal suspension has improved stability.

The fixture 36, the first frame 38 and the second frame 40 are each formed annularly and located concentrically to the intersection S, wherein the first frame 38 is located between the fixture 36 and the second frame 40.

The fixture 36 has a central cavity 60 that forms a channel 62 which extends completely through the framework 20 in the Z direction and opens into the holder 48.

The ray path runs in the channel 62 in this case, through said ray path the light of the light source 76 falls on the stamp 28.

The centroid of the structure-forming stamp surface 30 and the intersection S are preferably both on a mutual Z axis if the framework 20 is in a zero position.

The zero position of the framework 20 is the position in which the first frame 38 and the second frame 40 are aligned parallel to the fixture 36 as shown in FIGS. 2 and 3. In other words, the angle of rotation about the first rotational axis 56 and the second rotational axis 58 are each 0° in the zero position.

In an alternative embodiment, the fixture 36, the first frame 38 and the second frame 40 can each be configured in any way, for example as a U-shaped annular section.

In addition or alternatively, the fixture 36 and the second frame 40 can comprise swapped positions or swapped functions. In other words, the fixture 36 is located radially to the Z axis outside of the first frame 38 while the second frame 40 is located radially to the Z axis within the first frame 38, or the framework 20 is attached by means of the second frame 40 on the support 18 and the fixture 36 comprises the holder 48 for the stamp 28.

Moreover, the first rotational axis 56 and the second rotational axis 58 can be provided on any location of the first frame 38 and run towards each other in any way, in particular on the skew.

The joints 42, 44 are solid-state joints in the form of cross-spring joints and comprise only one single degree of freedom, namely one rotation about the corresponding rotational axis 56, 58 in any direction.

In this regard, the cross-spring joints are configured in such a way that they apply a force to the framework 20 in the direction of the zero position.

To this end, the cross-spring joints can be mounted in each case rotated to each other in pairs in order to realize an asymmetrical prestressing.

The joints 42, 44 as well as the fixture 36, the first frame 38 and the second frame 40 are configured in such a way that the first frame 38 can rotate about the first rotational axis 56 by a rotational angle of ±3.5° in relation to the zero position relative to the fixture 36 and the second frame 40 can rotate about the second rotational axis 58 by a rotational angle of ±3.5° in relation to the zero position relative to the first frame 38.

Fundamentally, the framework 20 can be configured in such a way that the first frame 38 and the second frame 40 can each rotate about the first rotational axis 56 or the second rotational axis 58 by any rotational angle, for example by ±5° in relation to the zero position.

The framework 20 also comprises two first stops 64 that limit the maximum permissible rotational angle between the first frame 38 and the fixture 36 about the first rotational axis 56 as well as two second stops 66 that limit the maximum permissible rotational angle between the second frame 40 and the first frame 38 about the second rotational axis 58.

The stops 64, 66 are adjustable in this regard, for example by means of an adjusting screw, thereby making it possible to adapt the corresponding maximum permissible rotational angle to different requirements.

Furthermore, the framework 20 comprises two first elastic elements 68 as well as two second elastic elements 70 that are each provided in the form of a spring.

The first elastic elements 68 thus couple the first frame 38 to the fixture 36 elastically while the second elastic elements 70 couple the first frame 38 to the second frame 40 elastically.

The elastic elements 68, 70 connect the first frame 38 to the fixture 36 and to the second frame 40 respectively at points of the largest cavity relative to each other, i.e. on the sides of the first frame 38 which comprises the largest spacing to the corresponding rotational axis 56, 58.

Furthermore, the elastic elements 68, 70 are located in each case on the opposing side of the first frame 38, i.e. the two first elastic elements 68 are provided on different sides of the first rotational axis 56 and the two second elastic elements 70 are provided on different sides of the second rotational axis 58.

The elastic elements 68, 70 are in addition each adjustable, for example by means of a setscrew so that by means of this the prestress can be set between the first frame 38 and the fixture 36 as well as the first frame 38 and the second frame 40. In this way, the alignment of the second frame 40 and thus the holder 48 as well as the stamp surface 30 can be set relative to the fixture 36.

The advantage of two first elastic elements 68 and two second elastic elements 70 respectively is that these can be mounted with restoring forces that are each opposite to one other in pairs in order to realize an asymmetrical prestressing of the first and/or second frame 38, 40.

The elastic elements 68, 70 are set in the present embodiment in such a way that the bottom side 54 of the second frame 40 and the holder 48 and thus the stamp surface 30 are aligned at an angle α of 1.5° to the reference plane 32 (see FIG. 4) if the framework 20 is a neutral position. The neutral position of the framework 20 is thus different from the zero position and is the position that the framework 20 occupies if there are no external forces, except gravity, acting on the framework 20, in particular in the assembled state.

In an alternative embodiment, the angle a can be between 0° and 5°, in particular between 1° and 2°.

In the embodiment shown in FIG. 2, each first stop 64 is integrated with a first elastic element 68 into a first sleeve-shaped component 72 in each case and each second stop 66 is integrated with a second elastic element 70 into a second sleeve-shaped component 74 in each case.

The sleeve-shaped components 72, 74 each have a sleeve that forms the corresponding stop 64, 66 and at the same time a guide for the corresponding elastic element 68, 70.

In an alternative embodiment, the elastic elements 68, 70 can be each provided separately to the stops 64, 66, i.e. spatially separate from each other and in particular not combined in a component 72, 74.

Of course, the first elastic elements 68 and/or the second elastic elements 70 can be configured in any way, for example in the form of an elastomer, in an alternative embodiment.

In addition or alternatively, only one single first elastic element 68 and/or one single second elastic element 70 can be provided in another alternative embodiment.

It is also conceivable, that the cross-spring joints form the elastic elements 68, 70.

Moreover, the first elastic elements 68 and/or the second elastic elements 70 can couple the first frame 38 with the fixture 36 and the second frame 40 with the first frame 38 at any point elastically.

The advantage of this configuration of the framework 20 is that the stamp surface 30 is located very closely to the rotational axes 56, 58. The spacing A between the rotational axes 56, 58 and the stamp surface 30 is 25 mm and the spacing B between the rotational axes 56, 58 and the holder 48 is 10 mm.

In an alternative embodiment, the spacing A and/or the spacing B are each a maximum of 15 mm, in particular a maximum of 10 mm.

In addition, the framework 20 is configured to be free from play.

The substrate 22 is attached to the chuck 16 in a first step for producing nanostructured and/or microstructured components.

In a further step, the stamp 28 is attached in the holder 48 and the framework 20 is adjusted by means of the adjustable elastic elements 68, 70 into the neutral position (see FIG. 4) so that the stamp surface 30 rests at an angle α of 1.5° obliquely to the reference plane 32.

Now the replication material 26 is applied to the stamp 28 by means of a metering unit 24.

In an alternative embodiment, the replication material 26 is applied to the point of the substrate 22 by means of a metering unit 24, at said point the nanostructure and/or microstructure are to be formed.

The substrate 22 is positioned by means of the XY table 14 relative to the stamp 28 so that the stamp surface 30 is located opposite the point at which the nanostructure and/or microstructure are to be formed.

In a subsequent step, the stamp 28 is moved into the Z direction towards the substrate 22 by means of the support 18 until the stamp 28 immerses in the replication material 26 and therefore imprints this.

The stamp supported elastically in the framework 20 aligns with the stamp surface 30 parallel to the reference plane 32 (see FIG. 5) as a result of the pressure applied via the support 18 in the Z direction and the resistance that is formed by the replication material 26 as well as the substrate 22.

By adjusting the stamp surface 30 and thus the holder 48, the second frame 40 pivots out of the neutral position, whereby a restoring force acts on the stamp 28.

The resulting force with which the stamp surface 30 is pressed against the replication material 26 as well as the substrate 22 is larger at the leading end 82 of the stamp 28, which is located nearer to the substrate 22 in the neutral position, than at the trailing end of the stamp 22, which is further away from the substrate 22 in the neutral position. The acting forces are shown in the FIGS. 5 and 6 by using simple arrows, whose length roughly corresponds to the magnitude of the respective force.

In a subsequent step, the replication material 26 is cured between the stamp surface 30 and the substrate 22 by means of a light source 76, thereby fixing the nanostructure and/or the microstructure in the replication material 26, said nanostructure and/or the microstructure having been imprinted by the stamp surface 30 in the replication material 26.

In a subsequent step, the stamp 28 is moved away from the substrate 22 by means of the support 18 counter to the Z direction.

As a result of the restoring force that the framework 20 exerts on the stamp 28 in the form of a torque, the stamp surface 30 initially detaches on the trailing end 84 and finally on the leading end 82 that remains in contact with the replication material 26 longer as a result of the framework 20 springing back into the neutral position or is pressed against the replication material 26 longer in the Z direction as a result of the framework 20 springing back into the neutral position.

In this way, the stamp 28 is removed from the replication material 26 continuously from the trailing end 84 to the leading end 82, thereby reducing the forces acting during the detachment and thus the risk that the nanostructures and/or microstructures formed in the replication material 26 are damaged during detachment.

The aforementioned steps are repeated in order to realize the step-and-repeat method by means of which the nanostructures and/or microstructures of the stamp surface 30 can be replicated on multiple points on the substrate 22.

In this way, a replication device 10 comprising a framework 20 is provided that has a simple assembly and guarantees a precise alignment of the stamp 28 free from play.

In particular, a passive wedge error of the stamp 28 to the substrate 22 can be compensated by means of the gimbal suspension of the framework 20 or a defined inclination of the stamp surface 30 in relation to the substrate 22 can be adjusted.

Furthermore, the gimbal suspension enables the placing of the rotational axes 56, 58 close to the contact point between stamp 28 and surface 34 of the substrate 22, thereby minimizing the lateral offset of the stamp 28 in the case of a displacement of the stamp 28.

Moreover, the framework 20 enables the assembly of a light source 76 in alignment over the stamp 28.

In addition, the framework 20 with an appropriate holder 48 is suitable as holding means for further heads, for example a mask or a substrate.

The disclosure is not limited to the shown embodiment. In particular, individual features of an embodiment can be combined in any way with features of another embodiment, in particular independently of the other features of the corresponding embodiments.

1. A framework for a replication device for producing at least one of nanostructured and microstructured components, comprising a fixture, a first frame and a second frame,
wherein the first frame is connected to the fixture by a first joint, wherein the first joint defines a first rotational axis about which the first frame is pivotable relative to the fixture,
wherein the second frame is connected to the first frame by a second joint, wherein the second joint defines a second rotational axis about which the second frame is pivotable relative to the first frame,
wherein the second frame comprises a holder for least one of a stamp, a mask and substrate.

2. The framework according to claim 1, wherein the first rotational axis and the second rotational axis run perpendicular to one another.

3. The framework according to claim 1, wherein first rotational axis and the second rotational axis run least one of in a plane and parallel to a reference plane of least one of the replication device and the holder.

4. The framework according to claim 1, wherein the holder is aligned in a neutral position of the framework obliquely to a reference plane.

5. The framework according to claim 4, wherein the holder is aligned in a neutral position of the framework obliquely to a reference plane at an angle between 0° and 5°.

6. The framework according to claim 1, wherein the first joint and the second joint each comprise only one degree of freedom.

7. The framework according to claim 6, wherein least one of the first and second joint is solid-state joint in each case.

8. The framework according to claim 1, wherein least one of the framework comprises at least a first elastic element by which the fixture is elastically connected to the first frame; and the framework comprises at least a second element by which the first frame is elastically connected to the second frame.

9. The framework according to claim 8, wherein least one of the first elastic element and the second elastic element are connected under prestress.

10. The framework according to claim 8, wherein least one of the first elastic element and the second elastic element are each a spring.

11. The framework according to claim 8, wherein least one of at least two first elastic elements and at least two second elastic elements are provided, wherein the least one of the two first elastic elements and the two second elastic elements are configured to apply different restoring forces.

12. The framework according to claim 1, wherein the framework comprises least one of a first stop, which is configured to limit the rotation of the first frame to the fixture about the first rotational axis; and a second stop that is configured to limit the rotation of the second frame to the first frame about the second rotational axis.

13. The framework according to claim 1, wherein the spacing between the holder and least one of the first rotation axis and the second rotational axis is a maximum of 15 mm.

14. The framework according to claim 1, wherein the first frame and the second frame are arranged with one within the other.

15. The framework according to claim 1, wherein the framework comprises a channel that extends perpendicularly away from the holder through least one of the fixture, the first frame and the second frame.

16. A replication device comprising a framework comprising a fixture, a first frame and a second frame,
wherein the first frame is connected to the fixture by a first joint, wherein the first joint defines a first rotational axis about which the first frame is pivotable relative to the fixture,
wherein the second frame is connected to the first frame by a second joint, wherein the second joint defines a second rotational axis about which the second frame is pivotable relative to the first frame,
wherein the second frame comprises a holder for least one of a stamp, a mask and substrate.

17. The replication device according to claim 16, wherein the replication device comprises a light source and a ray path that extends from the light source to the holder.

18. A method for producing least one of nanostructured and microstructured components by a lithographic method using a replication device, comprising the following steps:
a) providing a substrate
b) providing a stamp in a holder of the replication device,
c) moving least one of the stamp and the holder and the substrate towards each other relatively so that the stamp and the substrate occupy a parallel position to each other and a replication material provided between the stamp and the substrate is imprinted by the stamp, and
d) detaching the stamp, wherein the stamp is least one of prestressed and moved in a direction from the parallel position by a force.

19. The method according to claim 18, wherein least one of the stamp and the holder are aligned obliquely to the substrate before being moved relatively, wherein the least one of the stamp and the holder are prestressed in relation to the substrate by assuming the parallel position.

20. The method according to claim 18, wherein least one of the stamp and the holder are aligned obliquely to the substrate before being moved relatively at an angle between 0° and 5°, wherein the least one of the stamp and the holder are prestressed in relation to the substrate by assuming the parallel position
